(19) United States
(12) Patent Application Publication
(10) Pub. No.: US 2019/0181853 A1
(43) Pub. Date: Jun. 13, 2019

(54) SIGNAL OUTPUT CIRCUIT

(71) Applicant: DENSO CORPORATION, Kariya-city (JP)

(72) Inventors: Atsushi KOBAYASHI, Kariya-city (JP); Takeshi MATSUZAKI, Kariya-city (JP)

(21) Appl. No.: 16/278,278

(22) Filed: Feb. 18, 2019

Related U.S. Application Data
(63) Continuation of application No. PCT/JP2017/023966, filed on Jun. 29, 2017.

(30) Foreign Application Priority Data
Sep. 26, 2016 (JP) 2016-186953

(51) Int. Cl. H03K 17/16; H03K 4/94; H02M 1/08

(52) U.S. Cl. CPC H03K 17/162; H02M 3/07; H02M 1/08; H03K 4/94

(57) ABSTRACT

A signal output circuit is configured to control driving of an output transistor to output a trapezoidal wave output signal from a main terminal of the output transistor. The signal output circuit includes a driver that drives the output transistor at a constant current and a drive capability changing unit that periodically changes drive capability of the driver.

### CROSS REFERENCE TO RELATED APPLICATIONS

The present application is a continuation application of International Patent Application No. PCT/JP2017/023966 filed on Jun. 29, 2017, which designated the U.S. and claims the benefit of priority from Japanese Patent Application No. 2016-186953 filed on Sep. 26, 2016. The entire disclosures of all of the above applications are incorporated herein by reference.

### TECHNICAL FIELD

The present disclosure relates to a signal output circuit.

### BACKGROUND

A conventional signal output circuit controls driving of an output transistor to output a trapezoidal wave output signal from a main terminal of the output transistor.

### SUMMARY

The present disclosure provides a signal output circuit configured to control driving of an output transistor to output a trapezoidal wave output signal from a main terminal of the output transistor. The signal output circuit includes a driver that drives the output transistor at a constant current and a drive capability changing unit that periodically changes drive capability of the driver.

### BRIEF DESCRIPTION OF THE DRAWINGS

Additional objects and advantages of the present disclosure will be more readily apparent from the following detailed description when taken together with the accompanying drawings. In the drawings:

FIG. 1 is a diagram schematically showing a configuration of a switching regulator according to a first embodiment;

FIG. 2 is a diagram schematically showing a specific configuration example of a drive circuit;

FIG. 3 is a diagram schematically showing a specific configuration example of a voltage generation unit that generates a reference voltage;

FIG. 4 is a diagram schematically showing another specific configuration example of the voltage generation unit that generates the reference voltage;

FIG. 5 is a diagram schematically showing another specific configuration example of the voltage generation unit that generates the reference voltage;

FIG. 6 is a diagram schematically showing another specific configuration example of the voltage generation unit that generates the reference voltage;

FIG. 7 is a timing chart schematically showing an operation state of each unit, a signal waveform, and a voltage waveform;

FIG. 8 is a diagram schematically showing frequency spectrums of trapezoidal wave output in a case where two types of slew rates are provided and in a case where three types of slew rates are provided;

FIG. 9 is a graph schematically showing a frequency spectrum of the trapezoidal wave output in a case where a variation range of the slew rate is not devised;

FIG. 10 is a diagram schematically showing a specific configuration example of a variable resistor according to a second embodiment;

FIG. 11 is a timing chart schematically showing an operation state of each unit, a signal waveform, and a voltage waveform;

FIG. 12 is a diagram schematically showing a specific configuration example of a current mirror circuit according to a third embodiment;

FIG. 13 is a timing chart schematically showing an operation state of each unit, a signal waveform, and a voltage waveform;

FIG. 14 is a diagram schematically showing a specific configuration example of a drive circuit according to a fourth embodiment;

FIG. 15 is a timing chart schematically showing an operation state of each unit, a signal waveform, and a voltage waveform;

FIG. 16 is a timing chart schematically showing an operation state of each unit, a signal waveform, and a voltage waveform according to a fifth embodiment;

FIG. 17 is a timing chart in a sixth embodiment for explaining an issue caused by a surge voltage;

FIG. 18 is a diagram schematically showing a configuration of a switching regulator according to the sixth embodiment;

FIG. 19 is a timing chart schematically showing the operation state of each unit, the signal waveform, and the voltage waveform;

FIG. 20 is a diagram schematically showing a configuration of a charge pump circuit according to a seventh embodiment; and

FIG. 21 is a diagram schematically showing a configuration of a motor drive system.

### DETAILED DESCRIPTION

In a signal output circuit that outputs a trapezoidal wave, there is an issue that a harmonic component included in rise and fall of an output signal acts as a noise source and it is difficult to meet a standard for radio noise. In order to meet the standard, a noise suppression component such as a filter has to be separately provided, which causes increase in size and cost of a device.

In order to reduce a noise by the harmonic component, various techniques without providing the noise suppression component can be considered. For example, a technique according to a related art disperses a harmonic component by changing a slew rate of an output signal every time so as to suppress a peak value of a noise to a low value.

However, in the above-described related art, a constant voltage driving method is adopted as a method for driving a transistor in an output stage. Thus, in order to increase types of the slew rates, the number of buffers for driving the transistor in the output stage has to be increased, which cause increase in circuit scale.

A signal output circuit according to an aspect of the present disclosure is configured to control driving of an output transistor to output a trapezoidal wave output signal from a main terminal of the output transistor, and includes a driver and a drive capability changing unit. The driver drives the output transistor at a constant current. The drive capability changing unit periodically changes drive capability of the driver.

According to such a configuration, since the drive capability of the driver periodically changed, a slew rate of the trapezoidal wave output signal is periodically changed. As a result, a harmonic component contained in rise and fall of the output signal is dispersed, and thus a peak value of noise can be suppressed to a low value. In this case, a noise reduction effect is improved as the drive capability and further the number of change patterns of the slew rate are increased. In addition, in the above configuration, a constant current driving method for driving the output transistor at the constant current is adopted. Accordingly, the drive capability of the driver can be changed by only changing a current value. Thus, according to the above configuration, the change patterns of the slew rate can be increased without significantly increasing a circuit scale as in the related art. Therefore, a superior noise reduction effect can be obtained. As described above, according to the above configuration, such a superior effect that the noise of the harmonic component can be reduced while minimizing the circuit scale is obtained.

Hereinafter, multiple embodiments will be described with reference to the drawings. Hereinafter, in the respective embodiments, substantially the same configurations are denoted by identical symbols, and repetitive description will be omitted.

### First Embodiment

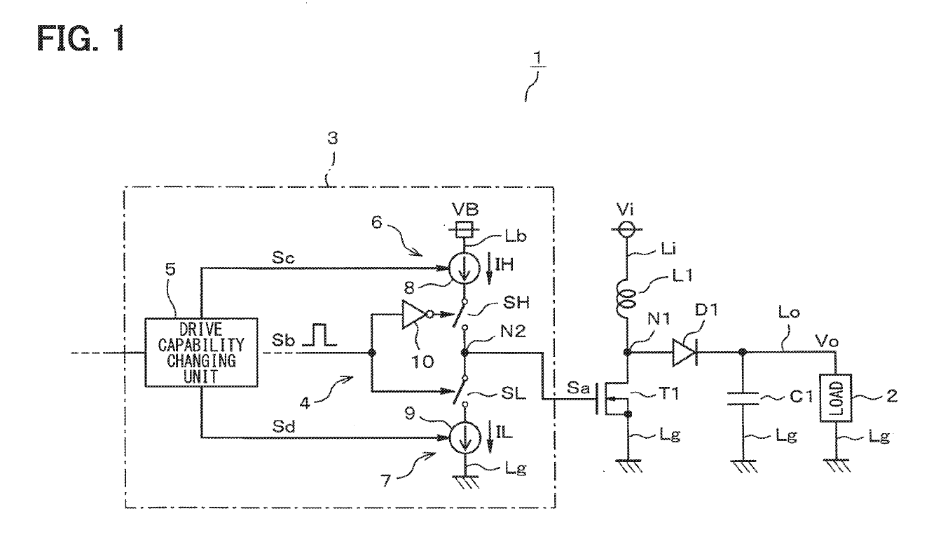

Hereinafter, a first embodiment will be described with reference to FIG. 1 to FIG. 9. A switching regulator 1 shown in FIG. 1 is provided in an electronic control device mounted on a vehicle, for example, and boosts and outputs an input voltage Vi received through an input power supply line Li. An output voltage Vo of the switching regulator 1 is supplied to a load 2 through an output power supply line Lo.

The switching regulator 1 includes an inductor L1, a diode D1, a capacitor C1, a transistor T1 as an n-channel MOS transistor, and a drive circuit 3. One terminal of the inductor L1 is connected to the input power supply line Li, and the other terminal of the inductor L1 is connected to the output power supply line Lo via the diode D1 in a forward direction. The capacitor C1 for smoothing is connected between the output power supply line Lo and a ground line Lg that receives a reference potential (0 V) of the circuit.

A drain of the transistor T1 is connected to a node N1 as a mutual connection point of the inductor L1 and the diode D1. A source of the transistor T1 is connected to the ground line Lg. A gate of the transistor T1 receives a drive signal Sa output from the drive circuit 3. That is, the drive circuit 3 controls on and off driving of the transistor T1. In this case, the driving of the transistor T1 is subjected to PWM control by the drive circuit 3. In this way, a boosting operation to boost and output the input voltage Vi is realized.

When such a boosting operation is executed, a trapezoidal wave signal appears at the drain of the transistor T1, that is, the node N1. Accordingly, in the present embodiment, the drive circuit 3 outputs a trapezoidal wave output signal (hereinafter also referred to as trapezoidal wave output) from the drain of the transistor T1 by controlling the driving of the transistor T1 and corresponds to a signal output circuit. In addition, in this case, the transistor T1 corresponds to an output transistor, and the drain of the transistor T1 corresponds to a main terminal.

The drive circuit 3 includes a driver 4 and a drive capability changing unit 5 that periodically changes drive capability of the driver 4. The driver 4 is configured to drive the transistor T1 at a constant current, and includes an on-side driver 6 that drives the transistor T1 on and an off-side driver 7 that drives the transistor T1 off.

The on-side driver 6 includes a current generation circuit 8 and a switch SH that is opened and closed at a position between the current generation circuit 8 and an output node N2 (hereinafter simply referred to as a node N2) of the drive circuit 3. The current generation circuit 8 generates a drive current IH flowing from a power supply line Lb, which receives a battery voltage VB, toward the node N2. The off-side driver 7 includes a current generation circuit 9 that generates a drive current IL flowing from the node N2 toward the ground line Lg, and a switch SL that is opened and closed at a position between the current generation circuit 9 and the node N2.

The switch SL is turned on when a control signal Sb for controlling the driving of the transistor T1 is at a high level (hereinafter referred to as an H level). The switch SL is turned off when the control signal Sb is at a low level (hereinafter referred to as an L level). Meanwhile, the switch SH is turned on when an inverted signal that is acquired by inverting the control signal Sb by an inverting buffer 10 is at the H level. The switch SH is turned off when the inverted signal is at the L level. Thus, each of the switches SL, SH is complementarily turned on and off on the basis of the control signal Sb.

According to such a configuration, in a period when the control signal Sb at the L level, the switch SH is turned on, and thus the drive current IH flows from the power supply line Lb toward the node N2 (=the gate of the transistor T1). Then, the transistor T1 is driven on by the drive current IH. Meanwhile, in a period when the control signal Sb is at the H level, the switch SL is turned on, and thus the drive current IL flows from the node N2 (=the gate of the transistor T1) toward the ground line Lg. Then, the transistor T1 is driven off by the drive current IL.

Magnitudes of the drive currents IH, IL respectively generated by the current generation circuits 8, 9, that is, current values are respectively set on the basis of current value command signals Sc, Sd provided from the drive capability changing unit 5. That is, the on-side driver 6 and the off-side driver 7 are configured to be able to change drive capability of the on-side driver 6 and the off-side driver 7, respectively. The drive capability changing unit 5 periodically changes the drive capability of the on-side driver 6 and the off-side driver 7, that is, the drive capability of the driver 4.

In this case, a switching time point at which the drive capability changing unit 5 changes the drive capability of the driver 4 is set in a period when the signal appearing at the drain of the transistor T1, that is, the trapezoidal wave output is not changed. Although the detailed description on the switching time point will be made below, the drive capability changing unit 5 changes the drive capability of the off-side driver 7 by using initiation of the on driving by the on-side driver 6 as a trigger, and changes the drive capability of the on-side driver 6 by using initiation of the off-driving by the off-side driver 7 as a trigger.

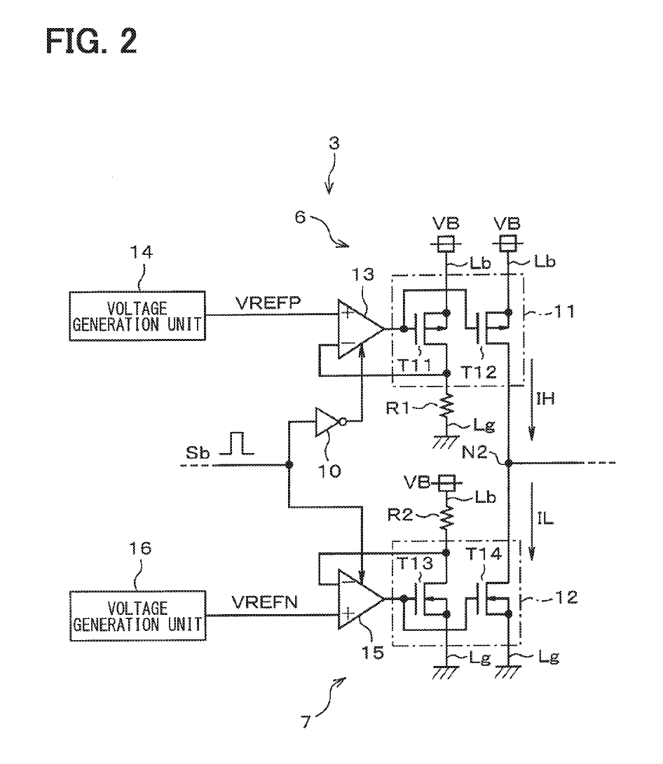

As a specific configuration of such a drive circuit 3, a configuration as shown in FIG. 2 can be adopted, for example. In the configuration shown in FIG. 2, a current mirror circuit 11 configured to include N units of p-channel MOS transistors is provided in an output stage of the on-side driver 6. In addition, a current mirror circuit 12 configured to include N units of the n-channel MOS transistors is provided in an output stage of the off-side driver 7. Here, N is an integer that is equal to or larger than 2. Note that, although FIG. 2 shows an example in which each of the current mirror circuits 11, 12 is configured to include the two transistors, that is, a configuration example of “N=2”, a configuration of “N≥3” may be adopted.

A source of a transistor T11 on an input side of the current mirror circuit 11 is connected to the power supply line Lb, and a drain of the transistor T11 is connected to the ground line Lg via a resistor R1. A source of a transistor T12 on an output side of the current mirror circuit 11 is connected to the power supply line Lb, and a drain of the transistor T12 is connected to the node N2. Gates of the transistors T11, T12 are connected to an output terminal of an operational amplifier 13.

A non-inverting input terminal of the operational amplifier 13 receives a reference voltage VREFP generated by a voltage generation unit 14. An inverting input terminal of the operational amplifier 13 is connected to the drain of the transistor T11. An operation of the operational amplifier 13 is switched between execution and termination on the basis of the inverted signal of the control signal Sb. More specifically, the operational amplifier 13 is switched to an operation state where the operation is executed when the inverted signal of the control signal Sb is at the H level. The operational amplifier 13 is switched to a non-operation state where the operation is terminated when the inverted signal of the control signal Sb is at the L level.

A source of a transistor T13 on an input side of the current mirror circuit 12 is connected to the ground line Lg, and a drain of the transistor T13 is connected to the power supply line Lb via a resistor R2. A source of a transistor T14 on an output side of the current mirror circuit 12 is connected to the ground line Lg, and a drain of the transistor T14 is connected to the node N2. Gates of the transistors T13, T14 are connected to an output terminal of an operational amplifier 15.

A non-inverting input terminal of the operational amplifier 15 receives a reference voltage VREFN generated by a voltage generation unit 16. An inverting input terminal of the operational amplifier 15 is connected to the drain of the transistor T13. An operation of the operational amplifier 15 is switched between execution and termination on the basis of the control signal Sb. More specifically, the operational amplifier 15 is switched to an operation state where the operation is executed when the control signal Sb is at the H level. The operational amplifier 15 is switched to a non-operation state where the operation is terminated when the control signal Sb is at the L level.

In this case, in the on-side driver 6, the operational amplifier 13 functions as the switch SH, and the current mirror circuit 11 and the resistor R1 function as the current generation circuit 8. Meanwhile, in the off-side driver 7, the operational amplifier 15 functions as the switch SL, and the current mirror circuit 12 and the resistor R2 function as the current generation circuit 9. Note that the voltage generation units 14, 16 are provided in the drive capability changing unit 5, and the reference voltages VREFP, VREFN respectively output from those voltage generation units 14, 16, function as the current value command signals Sc, Sd, respectively.

In the above configuration, a current IT11 flowing through the transistor T11 on the input side of the current mirror circuit 11 is determined by a value of the reference voltage VREFP and a resistance value R1 of the resistor R1 as expressed by the following expression (1).

IT11=VREFP/R1 (1)

Meanwhile, a current flowing through the transistor T12 on the output side of the current mirror circuit 11, that is, a current value of the drive current IH is expressed by the following expression (2).

IH=N×IT11=N×(VREFP/R1) (2)

In addition, in the above configuration, a current IT13 flowing through the transistor T13 on the input side of the current mirror circuit 12 is determined by a value of the battery voltage VB, a value of the reference voltage VREFN, and a resistance value R2 of the resistor R2 as expressed by the following expression (3).

IT13=(VB−VREFN)/R2 (3)

Meanwhile, a current flowing through the transistor T14 on the output side of the current mirror circuit 12, that is, a current value of the drive current IL is expressed by the following expression (4).

IL=N×IT13=N×((VB−VREFN)/R2) (4)

As described above, in the present embodiment, the magnitudes of the drive currents IH, IL and further the drive capability of the driver 4 can be changed by changing the currents on the input sides of the current mirror circuits 11, 12.

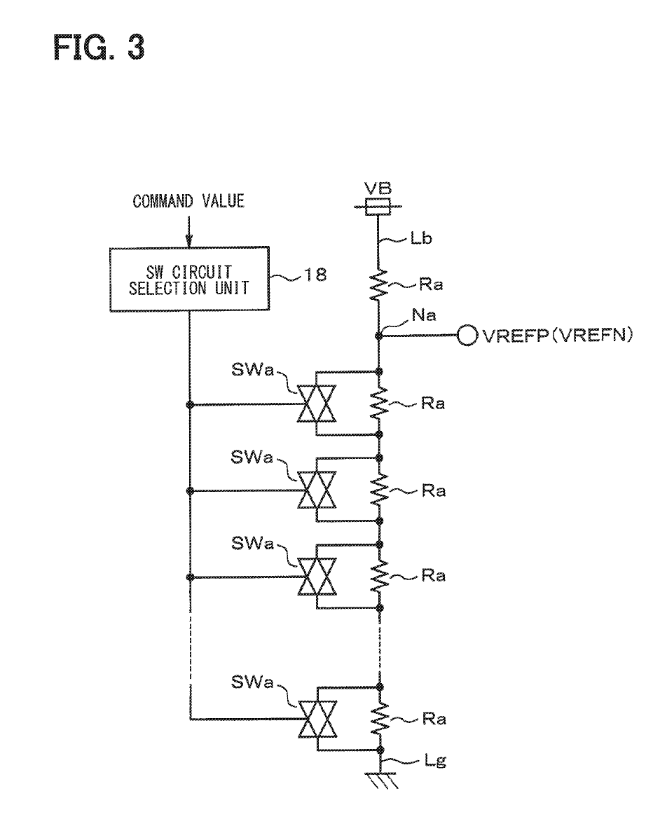

The voltage generation units 14, 16 are configured to switch voltage values of the reference voltages VREFP, VREFN to be output on the basis of a command value that commands the drive capability of the driver 4 (more specifically, the current values of the drive currents IH, IL), respectively. As a specific configuration of each of such voltage generation units 14, 16, any one of configurations as shown in FIG. 3 to FIG. 6 can be adopted, for example.

In the configuration shown in FIG. 3, the voltage value of the reference voltage VREFP (or the reference voltage VREFN) to be output is changed by switching a voltage division ratio of a resistance voltage divider circuit 17 that is connected between the power supply line Lb and the ground line Lg. In this case, of multiple resistors Ra that constitute the resistance voltage divider circuit 17, each of the resistors Ra other than the resistor Ra that is closest to the power supply line Lb (hereinafter referred to as the resistor Ra in a top stage) is provided with an analog switch SWa that is opened and closed at a position between both terminals of the corresponding resistor Ra.

An SW circuit selection unit 18 controls opening and closing of each of the analog switches SWa on the basis of the command value that commands the drive capability. In this way, the reference voltage VREFP (or the reference voltage VREFN) at the desired voltage value is output from a mutual connection node Na between the resistor Ra in the top stage and the resistor Ra connected to a downstream side of the resistor Ra in the top stage, both of which constitute the resistance voltage divider circuit 17.

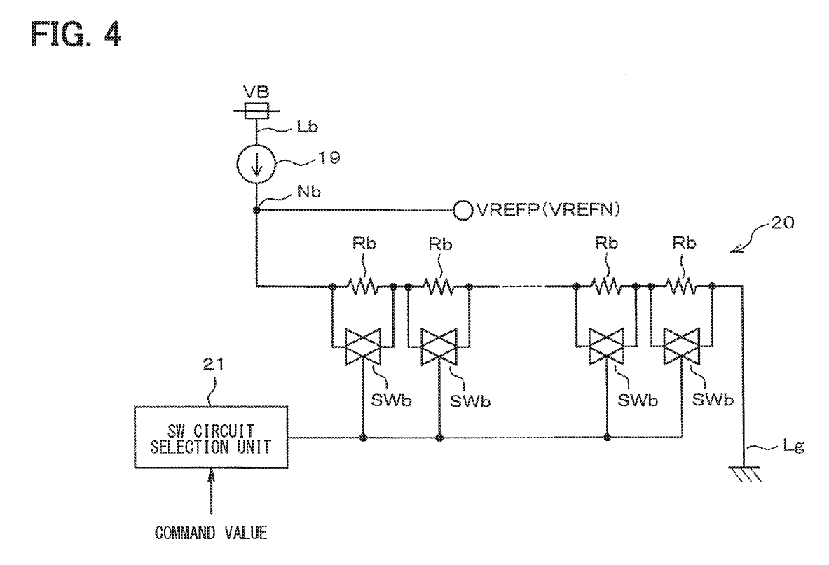

In the configuration shown in FIG. 4, the voltage value of the reference voltage VREFP (or the reference voltage VREFN) to be output is changed by switching a resistance value of a path, through which a current output from a constant current source 19 flows. In this case, the constant current source 19 and a resistance circuit 20 are connected between the power supply line Lb and the ground line Lg.

In addition, in this case, an analog switch SWb is provided to be opened and closed at a position between both terminals of each of all resistors Rb that constitute the resistance circuit 20. An SW circuit selection unit 21 controls opening and closing of each of the analog switches SWb on the basis of the command value that commands the drive capability. In this way, the reference voltage VREFP (or the reference voltage VREFN) at the desired voltage value is output from a mutual connection node Nb between the constant current source 19 and the resistance circuit 20.

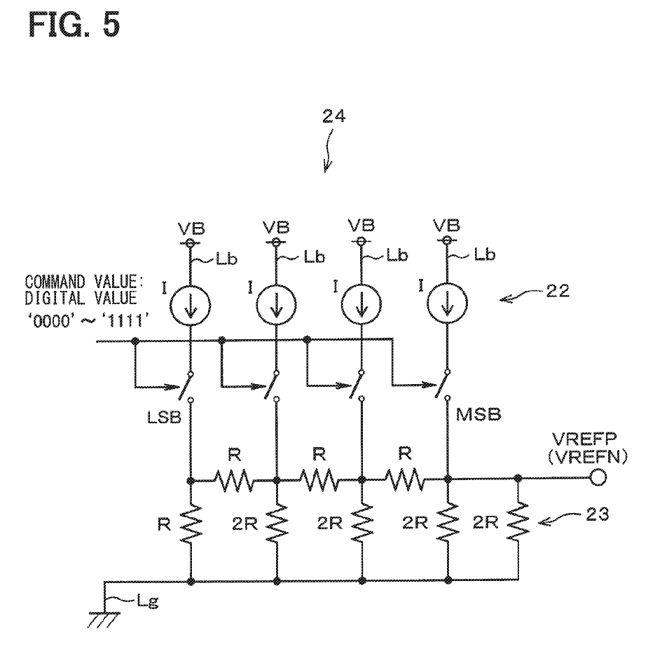

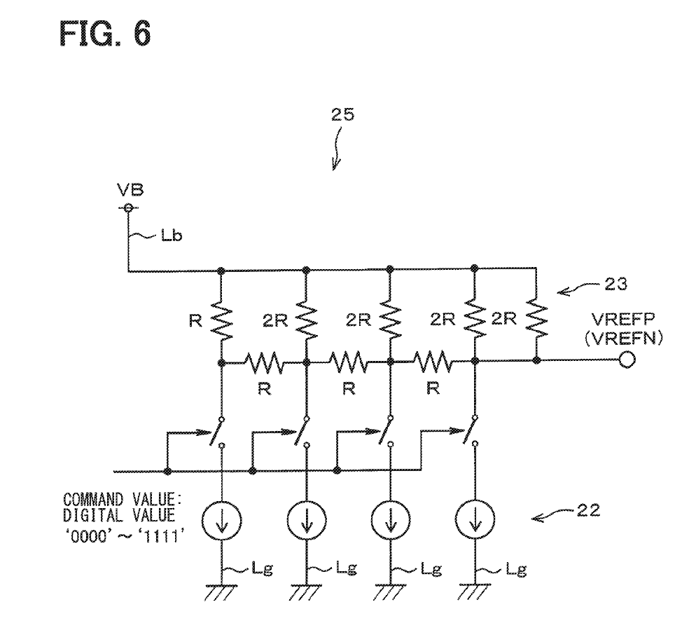

A configuration shown in FIG. 5 is a D/A converter 24 that has 4-bit resolution using a constant current circuit 22 and an R-2R ladder circuit 23. In this case, the voltage value of the reference voltage VREFP (or the reference voltage VREFN) to be output can be changed on the basis of a command value as a 4-bit digital value. Note that the number of bits is not limited to “4” and may appropriately be changed in accordance a change range of the required voltage value or the like. In addition, arranged positions of the constant current circuit 22 and the R-2R ladder circuit 23 can be switched. In this case, a D/A converter 25 with a configuration as shown in FIG. 6 is acquired.

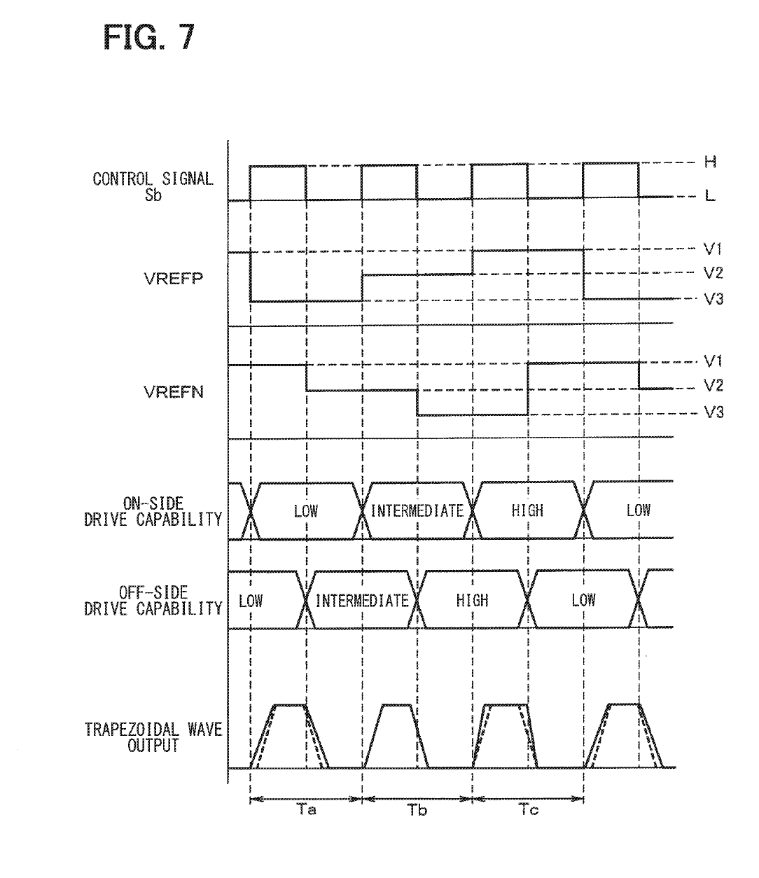

Next, action of the configuration described above will be described. Here, a description will be made on the operation state of each of the units in a case where the drive capability changing unit 5 changes the drive capability of the driver 4 every drive cycle (PWM cycle) of the transistor T1 with reference to FIG. 7. In this case, the drive capability of each of the on-side driver 6 and the off-side driver 7 is changed to one of three types (three stages) of “low”, “intermediate”, and “high”. An order of the change is “low→intermediate→high→low→intermediate→high . . . .”

In the above configuration, the drive capability of the on-side driver 6 (hereinafter also referred to as on-side drive capability) is increased as the voltage value of the reference voltage VREFP is increased. In this case, the on-side drive capability becomes “high” when the voltage value of the reference voltage VREFP is V1, becomes “intermediate” when the voltage value of the reference voltage VREFP is V2, and becomes “low” when the voltage value of the reference voltage VREFP is V3. Note that a magnitude relationship of the voltage values V1 to V3 is “V1>V2>V3”.

In addition, in the above configuration, the drive capability of the off-side driver 7 (hereinafter also referred to as off-side drive capability) is increased as the voltage value of the reference voltage VREFN is decreased. In this case, the off-side drive capability becomes “low” when the voltage value of the reference voltage VREFN is V1, becomes “intermediate” when the voltage value of the reference voltage VREFN is V2, and becomes “high” when the voltage value of the reference voltage VREFN is V3.

As shown in FIG. 7, the voltage value of the reference voltage VREFP is switched at a time point at which the control signal Sb is changed from the L level to the H level, that is, rise timing of the control signal Sb. In this way, the on-side drive capability is switched. Meanwhile, the voltage value of the reference voltage VREFN is switched at a time point at which the control signal Sb is changed from the H level to the L level, that is, fall timing of the control signal Sb. In this way, the off-side drive capability is switched.

Since the on-side drive capability and the off-side drive capability are switched, just as described, a slew rate of the trapezoidal wave output is changed every cycle. More specifically, in a period Ta, the off-side drive capability is “low” at the rise timing of the trapezoidal wave output, and the on-side drive capability is “low” at the fall timing of the trapezoidal wave output. Thus, in the period Ta, rise and fall gradients of the trapezoidal wave output are the least steep, and the slew rate of the trapezoidal wave output is the lowest. Note that, in FIG. 7, in order to facilitate understanding of the change in the slew rate of the trapezoidal wave output, a waveform of the trapezoidal wave output in a case where the drive capability is “intermediate” is indicated by dotted lines.

In a period Tb, the off-side drive capability is “intermediate” at the rise timing of the trapezoidal wave output, and the on-side drive capability is “intermediate” at the fall timing of the trapezoidal wave output. Thus, in the period Tb, the rise and fall gradients of the trapezoidal wave output are steeper than the rise and fall gradients of the trapezoidal wave output in the period Ta, and the slew rate of the trapezoidal wave output is higher than the slew rate of the trapezoidal wave output in the period Ta.

In a period Tc, the off-side drive capability is “high” at the rise timing of the trapezoidal wave output, and the on-side drive capability is high” at the fall timing of the trapezoidal wave output. Thus, in the period Tc, the rise and fall gradients of the trapezoidal wave output are the steepest, and the slew rate of the trapezoidal wave output is the highest.

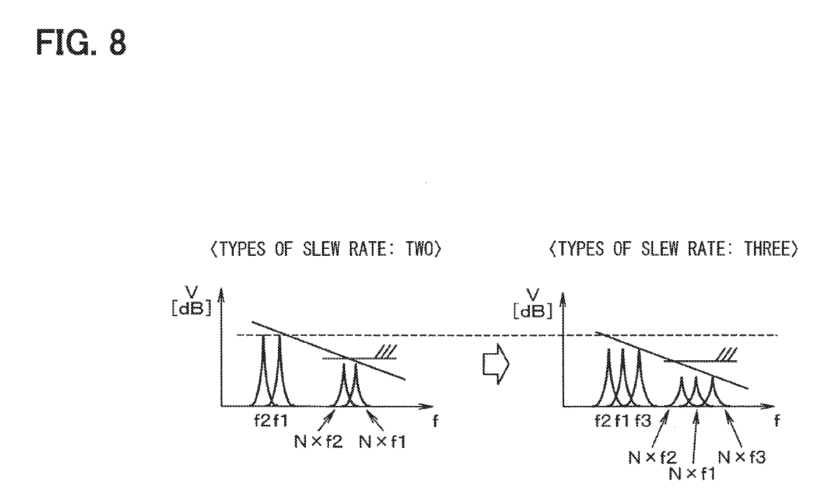

According to the present embodiment described above, the following effects can be obtained. In the present embodiment, since the drive capability of the driver 4 is periodically changed, the slew rate of the trapezoidal wave output is periodically changed. As a result, a harmonic component contained in the rise and the fall of the trapezoidal wave output is dispersed, and thus a peak value of noise can be suppressed to a low value. In this case, a noise reduction effect is improved as the drive capability and further the number of change patterns of the slew rate are increased. As shown in FIG. 8, it is understood that the higher noise reduction effect is obtained when three types of the slew rates are provided than when two types of the slew rates are provided.

Here, in the present embodiment, since a constant current driving method for driving the transistor T1 at the constant current is adopted, the drive capability of the transistor T1 can be changed by only changing the current values of the drive currents 1H, IL. Thus, according to the present embodiment, the change patterns of the slew rate can be increased without significantly increasing a circuit scale as in the related art. Therefore, the superior noise reduction effect can be obtained. As described above, according to the present embodiment, such a superior effect that the noise of the harmonic component can be reduced while minimizing the circuit scale is obtained.

The drive capability changing unit 5 changes the drive capability of the off-side driver 7 by using the fall of the control signal Sb, that is, the initiation of the on driving by the on-side driver 6 as the trigger, and changes the drive capability of the on-side driver 6 by using the rise of the control signal Sb, that is, the initiation of the off-driving by the off-side driver 7 as the trigger. Thus, the drive capability of the driver 4 is changed in a period when the trapezoidal wave output is not changed. In this way, the gradient of the trapezoidal wave output is not changed in the middle of the rise of the trapezoidal wave output and in the middle of the fall of the trapezoidal wave output.

In addition, the drive capability changing unit 5 changes the magnitudes of the drive current IH of the on-side driver 6 and the drive current IL of the off-side driver 7 by changing the voltage values of the reference voltages VREFP, VREFN, which are respectively generated by the voltage generation units 14, 16. In this way, the drive capability of the driver 4 is changed. As the specific configuration of each of the voltage generation units 14, 16, which respectively switch the voltage values of the reference voltages VREFP, VREFN to be generated, a general and simple configuration as shown in each of FIG. 3 to FIG. 6 can be adopted. Thus, according to the present embodiment, the drive capability of the driver 4 can be changed without significantly increasing the circuit scale.

The drive capability changing unit 5 changes the drive capability of the driver 4 every PWM cycle. The reason for the change of the drive capability of the driver 4 every PWM cycle is as follows. In the switching regulator 1, loss is increased as the drive capability of the driver 4 is lowered, and the loss is decreased as the drive capability of the driver 4 is increased. That is, when the drive capability is changed, a degree of power loss in the switching regulator 1 is changed. However, as in the present embodiment, in a case where the drive capability is changed every PWM cycle, a variation in the loss does not appear clearly. Thus, there is no risk that an operation of the switching regulator 1 is significantly changed from the operation of the switching regulator in the related art.

For example, in a case where the drive capability of the driver 4 is changed between two types of the drive capability, the drive capability changing unit 5 preferably changes the drive capability such that a difference between the slew rate of the trapezoidal wave output before the change of the drive capability and the slew rate of the trapezoidal wave output after the change of the drive capability becomes smaller than a predetermined threshold. In this case, the threshold is preferably set such that the least common multiple of a frequency determined at the slew rate of the trapezoidal wave output before the change of the drive capability and the frequency determined at the slew rate of the trapezoidal wave output after the change of the drive capability becomes equal to or higher than a predetermined frequency.

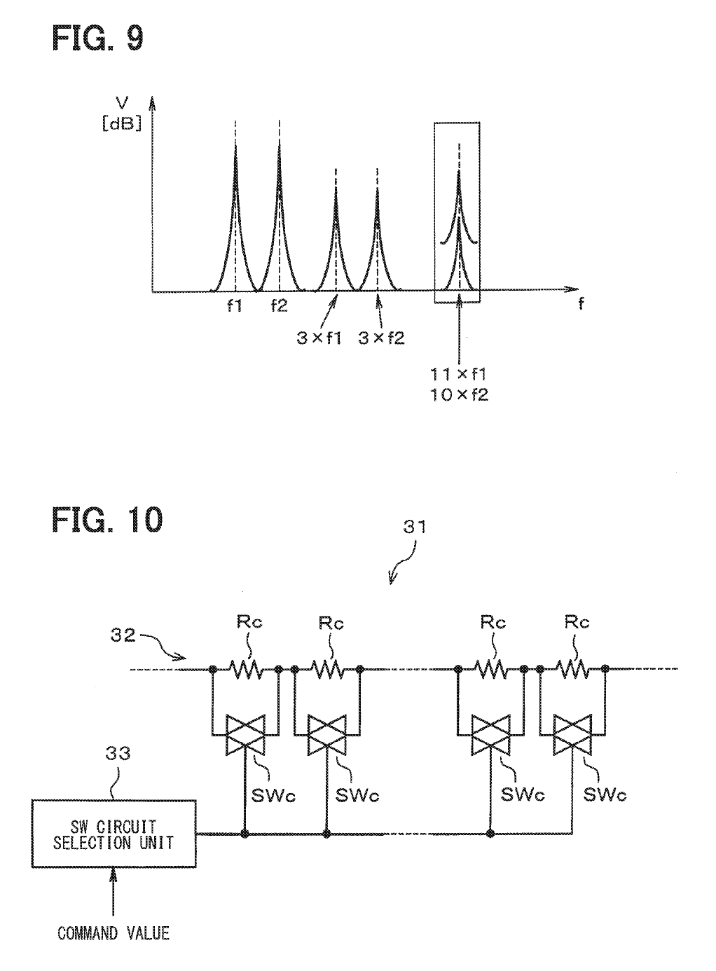

The following effect is obtained by devising a variation range of the slew rate as described above. A case where the harmonic component of the trapezoidal wave output is dispersed to frequencies f1, f2 as a result of providing the two types of the slew rates, for example, without devising the variation range of the slew rate is considered. In this case, frequency components of integral multiples of the frequencies f1, f2 are contained. Here, it is assumed that “f1:f2=1:1.1”. In this case, as shown in FIG. 9, the frequency that is 11 times as high as f1 and the frequency that is 10 times as high as f2 become the same frequency. In this case, as shown in FIG. 9, the frequency that is 11 times as high as f1 and the frequency that is 10 times as high as f2 become the same frequency. Accordingly, noise peaks overlap each other at every 11×n (here, n is a positive integer), and thus the noise reduction effect cannot be obtained at the frequency of 11×n.

On the contrary, a case where the harmonic component of the trapezoidal wave output is dispersed to the frequencies f1, f2 as a result of providing the two types of the slew rates and devising the variation range of the slew rate as described above is considered. In this case, the variation range of the slew rate is set such that the least common multiples of the frequencies f1, f2 become equal to or higher than the predetermined frequency. For example, it is assumed that “f1:f2=1:1.07”. In this case, the noise peaks overlap each other only at every 107×n. That is, when the variation range of the slew rate is devised as described above, the noise peaks can overlap each other with significantly less frequency than a case where the variation range of the slew rate is not devised.

### Second Embodiment

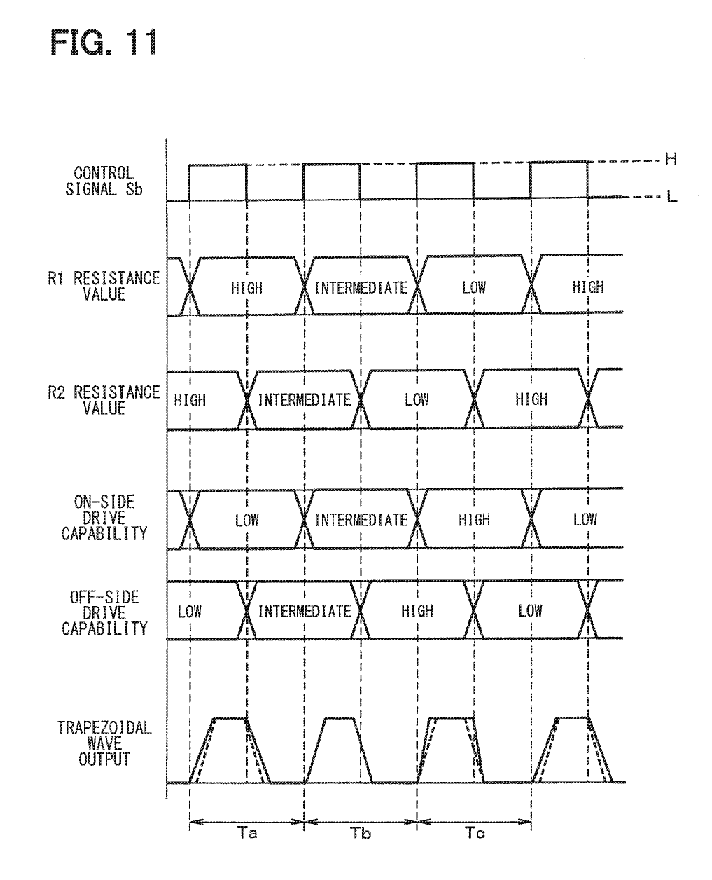

A second embodiment will hereinafter be described with reference to FIG. 10 and FIG. 11. In the first embodiment, the magnitudes of the drive currents IH, IL and further the drive capability of the driver 4 are changed by switching the voltage values of the reference voltages VREFP, VREFN, which are respectively generated by the voltage generation units 14, 16. However, as it is apparent from the expression (2) and the expression (4) described above, the magnitudes of the drive currents IH, IL depend not only on the reference voltages VREFP, VREFN but also on the resistance values of the resistors R1, R2. Thus, in the present embodiment, a description will be made on a configuration to change the magnitudes of the drive currents IH, IL by switching the resistance values of the resistors R1, R2.

In this case, the voltage generation units 14, 16 respectively generate the reference voltages VREFP, VREFN at the constant voltage values. In addition, each of the resistors R1, R2 is changed to a variable resistor that can change the resistance value as shown in FIG. 10. A variable resistor 31 shown in FIG. 10 includes a resistance circuit 32 configured to include multiple resistors Rc that are connected in series and an analog switch SWc that is opened and closed at a position between both terminals of each of the multiple resistors Rc. In addition, an SW circuit selection unit 33 controls opening and closing of each of the analog switches SWc on the basis of the command value that commands the drive capability.

According to such a configuration, the resistance values of the resistors R1, R2 can be changed on the basis of the command value. In this case, the drive currents IH, IL are decreased as the resistance values of the resistors R1, R2 are increased, and the drive currents IH, IL are increased as the resistance values of those resistors R1, R2 are decreased. That is, the on-side drive capability is decreased as the resistance value of the resistor R1 is increased, and the on-side drive capability is increased as the resistance value of the resistor R1 is decreased. Meanwhile, the off-side drive capability is decreased as the resistance value of the resistor R2 is increased, and the off-side drive capability is increased as the resistance value of the resistor R2 is decreased.

Next, operation and effects of the present embodiment will be described with reference to FIG. 11. In this case, change intervals, the types, and the like of the drive capability are similar to the change intervals, the types, and the like in the first embodiment. In addition, in this case, the on-side drive capability is increased as the resistance value of the resistor R1 is decreased. Thus, the on-side drive capability becomes “low” when the resistance value of the resistor R1 is “high”, becomes “intermediate” when the resistance value of the resistor R1 is “intermediate”, and becomes “high” when the resistance value of the resistor R1 is “low”, Furthermore, the off-side drive capability is increased as the resistance value of the resistor R2 is decreased. Thus, the off-side drive capability becomes “low” when the resistance value of the resistor R2 is “high”, becomes “intermediate” when the resistance value of the resistor R2 is “intermediate”, and becomes “high” when the resistance value of the resistor R2 is “low”.

As shown in FIG. 11, in this case, the resistance value of the resistor R1 is switched at the rise timing of the control signal Sb, and thus the on-side drive capability is switched. Meanwhile, the resistance value of the resistor R2 is switched at the fall timing of the control signal Sb, and thus the off-side drive capability is switched. That is, also in this case, the on-side drive capability and the off-side drive capability are switched in a similar manner to the first embodiment. As a result, the slew rate of the trapezoidal wave output is changed in the same mode as in the first embodiment. Therefore, according to the present embodiment, the same effects as in the first embodiment are obtained.

### Third Embodiment

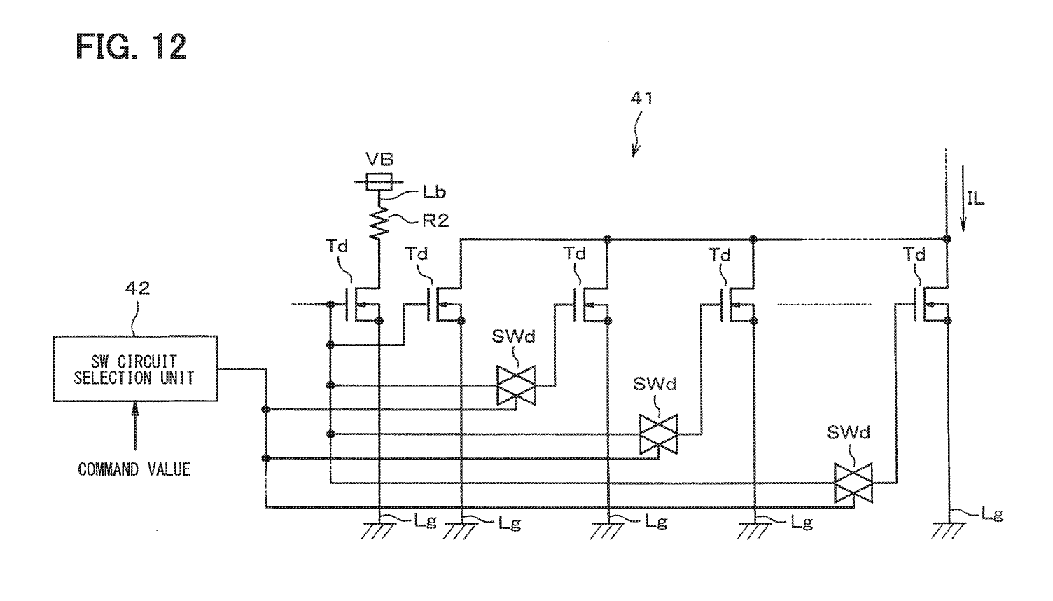

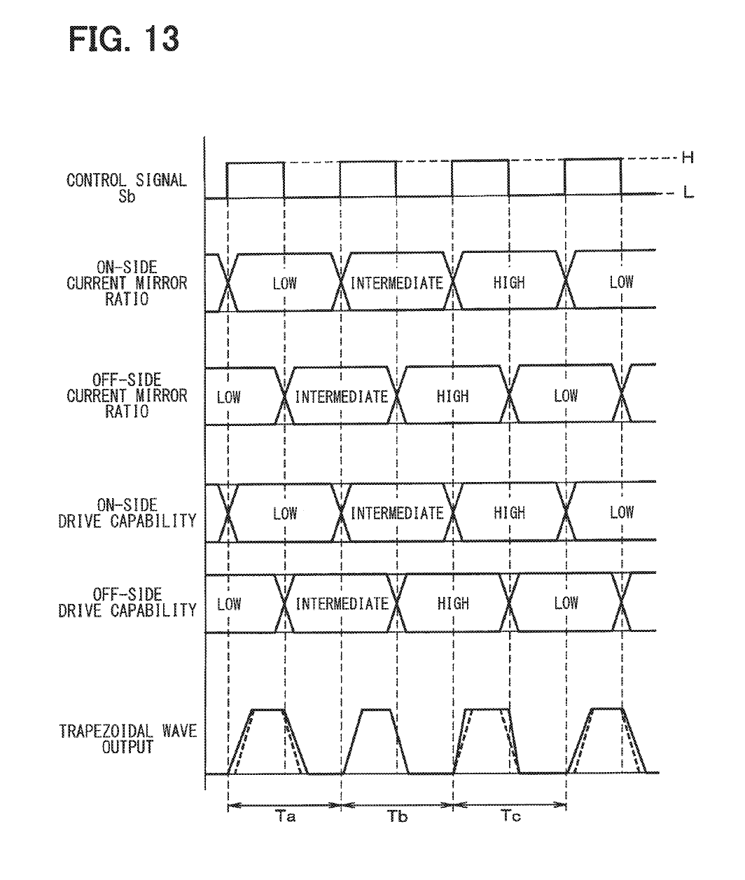

A third embodiment will hereinafter be described with reference to FIG. 12 and FIG. 13. In the first embodiment, the magnitudes of the drive currents IH, IL and further the drive capability of the driver 4 are changed by switching the voltage values of the reference voltages VREFP, VREFN, which are respectively generated by the voltage generation units 14, 16. However, as it is apparent from the expression (2) and the expression (4) described above, the magnitudes of the drive currents H, IL depend not only on the reference voltages VREFP, VREFN but also on a mirror ratio (=N) of each of the current mirror circuits 11, 12. Thus, in the present embodiment, a description will be made on a configuration to change the magnitudes of the drive currents H, IL by switching the mirror ratios of the current mirror circuits 11, 12.

In this case, the voltage generation units 14, 16 respectively generate the reference voltages VREFP, VREFN at the constant voltage values. In addition, the current mirror circuits 11, 12 are changed to have configurations capable of changing the mirror ratios of the current mirror circuits 11, 12. As a specific configuration of the current mirror circuit capable of changing the mirror ratio, a configuration as shown in FIG. 12 can be adopted, for example. Here, FIG. 12 shows a configuration corresponding to the current mirror circuit 12, which generating the drive current IL. However, the same configuration can be adopted for the current mirror circuit 11, which generating the drive current IH.

A current mirror circuit 41 shown in FIG. 12 is configured to include multiple n-channel MOS transistors Td. In this case, a gate of the transistor Td whose drain is connected to the resistor R2 (hereinafter referred to as the input-side transistor Td) and a gate of the transistor Td in a next stage are directly connected to each other. In addition, the gate of the input-side transistor Td and a gate of each of the other transistors Td are connected via an analog switch SWd. Furthermore, an SW circuit selection unit 42 controls opening and closing of each of the analog switches SWd on the basis of the command value that commands the drive capability.

When such a configuration is adopted as each of the current mirror circuits 11, 12, the mirror ratio of each of the current mirror circuits 11, 12 can be changed on the basis of the command value. In addition, in this case, the drive currents IH, IL are decreased as the mirror ratios of the current mirror circuits 11, 12 are decreased, and the drive currents IH, IL are increased as the mirror ratios of those current mirror circuits 11, 12 are increased.

That is, the on-side drive capability is decreased as the mirror ratio of the current mirror circuit 11 (hereinafter also referred to as an on-side current mirror ratio) is decreased, and the on-side drive capability is increased as the mirror ratio of the current mirror circuit 11 is increased. In addition, the off-side drive capability is decreased as the mirror ratio of the current mirror circuit 12 (hereinafter also referred to as an off-side current mirror ratio) is decreased, and the off-side drive capability is increased as the mirror ratio of the current mirror circuit 12 is increased.

Next, operation and effects of the present embodiment will be described with reference to FIG. 13. In this case, change intervals, the types, and the like of the drive capability are similar to the change intervals, the types, and the like in the first embodiment. In addition, in this case, the on-side drive capability is increased as the on-side current mirror ratio is increased. Thus, the on-side drive capability becomes “low” when the on-side current mirror ratio is “low”, becomes “intermediate” when the on-side current mirror ratio is “intermediate”, and becomes “high” when the on-side current mirror ratio is “high”. Furthermore, the off-side drive capability is increased as the off-side current mirror ratio is increased. Thus, the off-side drive capability becomes “low” when the off-side current mirror ratio is “low”, becomes “intermediate” when the off-side current mirror ratio is “intermediate”, and becomes “high” when the off-side current mirror ratio is “high”.

As shown in FIG. 13, in this case, the on-side current mirror ratio is switched at the rise timing of the control signal Sb, and thus the on-side drive capability is switched. Meanwhile, the off-side current mirror ratio is switched at the fall timing of the control signal Sb, and thus the off-side drive capability is switched. That is, also in this case, the on-side drive capability and the off-side drive capability are switched in a similar manner to the first embodiment. As a result, the slew rate of the trapezoidal wave output is changed in the same mode as in the first embodiment. Therefore, according to the present embodiment, the same effects as in the first embodiment are obtained.

Furthermore, in the present embodiment, the drive capability is changed by switching the mirror ratios of the current mirror circuits 11, 12. That is, in this case, in the drive circuit 3, the drive capability is changed by switching a portion closest to the node N1, in which the trapezoidal wave output appears. Thus, responsiveness of the change of the drive capability is favorable.

### Fourth Embodiment

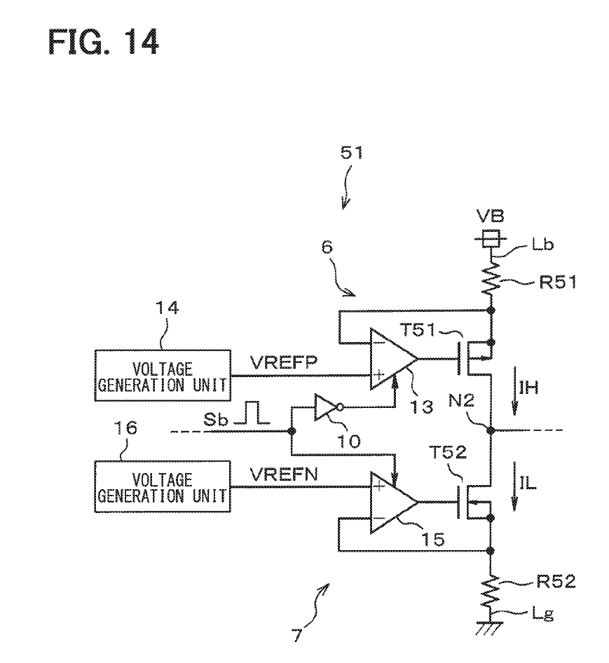

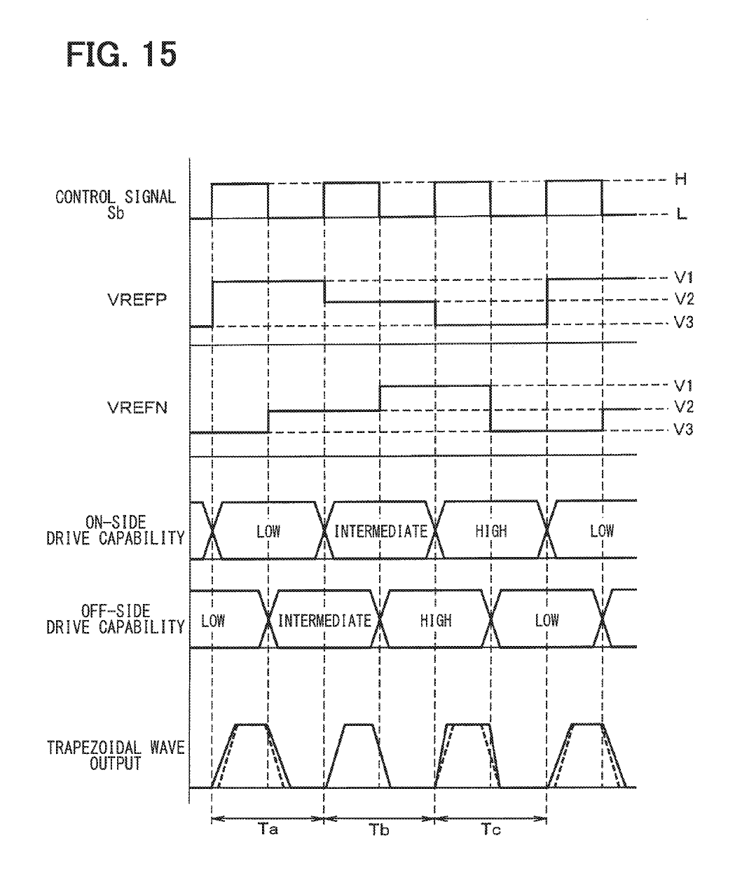

A fourth embodiment will hereinafter be described with reference to FIG. 14 and FIG. 15. In the specific configuration of the drive circuit 3 in the first embodiment, which is shown in FIG. 2, the current mirror circuit 11 is provided in the output stage of the on-side driver 6, and the current mirror circuit 12 is provided in the output stage of the off-side driver 7. However, the configuration of the drive circuit 3 in the first embodiment can be changed to a configuration in which a single transistor is provided in the output stage of each of the on-side driver 6 and the off-side driver 7.

As a specific configuration of a drive circuit that is modified as described above, a configuration as shown in FIG. 14 can be adopted, for example. A drive circuit 51 shown in FIG. 14 differs from the drive circuit 3 shown in FIG. 2 in a point that a transistor T51 as the p-channel MOS transistor is provided instead of the current mirror circuit 11, a point that a transistor T52 as the n-channel MOS transistor is provided instead of the current mirror circuit 12, a point that resistors R51, R52 are provided instead of the resistors R1, R2, and the like.

A source of the transistor T51 is connected to the power supply line Lb via the resistor R51, and a drain of the transistor T51 is connected to the node N2. A gate of the transistor T51 is connected to the output terminal of the operational amplifier 13. The inverting input terminal of the operational amplifier 13 is connected to the source of the transistor T51.

A source of the transistor T52 is connected to the ground line Lg via the resistor R52, and a drain of the transistor T52 is connected to the node N2. A gate of the transistor T52 is connected to the output terminal of the operational amplifier 15. The inverting input terminal of the operational amplifier 15 is connected to the source of the transistor T52.

Note that, in this case, in the on-side driver 6, the operational amplifier 13 functions as the switch SH, and the transistor T51 and the resistor R51 function as the current generation circuit 8. Meanwhile, in the off-side driver 7, the operational amplifier 15 functions as the switch SL, and the transistor T52 and the resistor R52 function as the current generation circuit 9.

In the above configuration, a current flowing through the transistor T51, that is, the current value of the drive current IH is determined by the value of the battery voltage VB, the value of the reference voltage VREFP, and a resistance value R51 of the resistor R51 as expressed by the following expression (5).

IH=(VB−VREFP)/R51 (5)

In addition, in the above configuration, a current flowing through the transistor T52, that is, the current value of the drive current IL is determined by the value of the reference voltage VREFN and a resistance value R52 of the resistor R52 as expressed by the following expression (6).

IL=VREFN/R52 (6)

Similar to the first embodiment, the voltage generation units 14, 16 switch the voltage values of the reference voltages VREFP, VREFN to be output on the basis of the command value that commands the drive capability of the driver 4, respectively. Thus, as specific configurations of the voltage generation units 14, 16 in the present embodiment, similar configurations to the configurations in the first embodiment can be adopted.

Next, operation and effects of the present embodiment will be described with reference to FIG. 15. In this case, change intervals, the types, and the like of the drive capability are similar to the change intervals, the types, and the like in the first embodiment. In addition, in this case, the on-side drive capability is increased as the voltage value of the reference voltage VREFP is decreased. Thus, the on-side drive capability becomes “low” when the voltage value of the reference voltage VREFP is V1, becomes “intermediate” when the voltage value of the reference voltage VREFP is V2, and becomes “high” when the voltage value of the reference voltage VREFP is V3. Furthermore, the off-side drive capability is increased as the voltage value of the reference voltage VREFN is increased. Thus, the off-side drive capability becomes “high” when the voltage value of the reference voltage VREFN is V1, becomes “intermediate” when the voltage value of the reference voltage VREFN is V2, and becomes “low” when the voltage value of the reference voltage VREFN is V3.

As shown in FIG. 15, in this case, the voltage value of the reference voltage VREFP is switched at the rise timing of the control signal Sb, and thus the on-side drive capability is switched. Meanwhile, the voltage value of the reference voltage VREFN is switched at the fall timing of the control signal Sb, and thus the off-side drive capability is switched. That is, also in this case, the on-side drive capability and the off-side drive capability are switched in a similar manner to the first embodiment. As a result, the slew rate of the trapezoidal wave output is changed in the same mode as in the first embodiment. Therefore, according to the present embodiment, the same effects as in the first embodiment are obtained.

### Fifth Embodiment

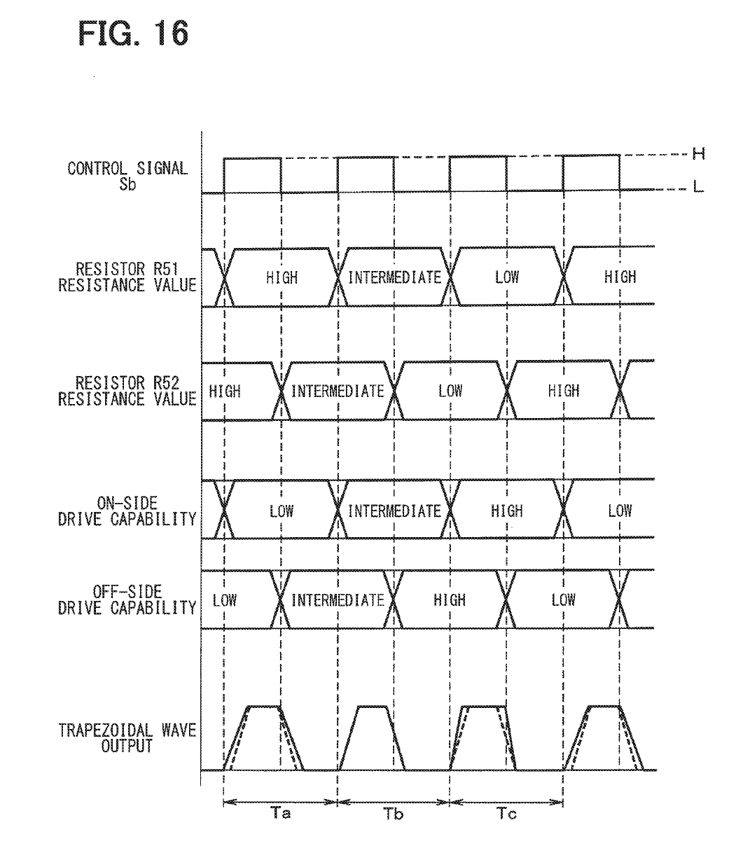

Hereinafter, a fifth embodiment will be described with reference to FIG. 16. In the fourth embodiment, the magnitudes of the drive currents IH, IL and further the drive capability of the driver 4 are changed by switching the voltage values of the reference voltages VREFP, VREFN, which are respectively generated by the voltage generation units 14, 16. However, as it is apparent from the expression (5) and the expression (6) described above, the magnitudes of the drive currents IH, IL depend not only on the reference voltages VREFP, VREFN but also on the resistance values of the resistors R51, R52. Thus, in the present embodiment, a description will be made on a configuration to change the magnitudes of the drive currents IH, IL by switching the resistance values of the resistors R51, R52.

In this case, the voltage generation units 14, 16 respectively generate the reference voltages VREFP, VREFN at the constant voltage values. In addition, each of the resistors R51, R52 is changed to the variable resistor that can change the resistance value as shown in FIG. 10. According to such a configuration, the resistance values of the resistors R51, R52 can be changed on the basis of the command value.

In this case, the drive currents IH, IL are decreased as the resistance values of the resistors R51, R52 are increased, and the drive currents IH, IL are increased as the resistance values of those resistors R51, R52 are decreased. That is, the on-side drive capability is decreased as the resistance value of the resistor R51 is increased, and the on-side drive capability is increased as the resistance value of the resistor R51 is decreased. Meanwhile, the off-side drive capability is decreased as the resistance value of the resistor R52 is increased, and the off-side drive capability is increased as the resistance value of the resistor R52 is decreased.

Next, operation and effects of the present embodiment will be described with reference to FIG. 16. In this case, change intervals, the types, and the like of the drive capability are similar to the change intervals, the types, and the like in the first embodiment. In addition, in this case, the on-side drive capability is increased as the resistance value of the resistor R51 is decreased. Thus, the on-side drive capability becomes “low” when the resistance value of the resistor R51 is “high”, becomes “intermediate” when the resistance value of the resistor R51 is “intermediate”, and becomes “high” when the resistance value of the resistor R51 is “low”. Furthermore, the off-side drive capability is increased as the resistance value of the resistor R52 is decreased. Thus, the off-side drive capability becomes “low” when the resistance value of the resistor R52 is “high”, becomes “intermediate” when the resistance value of the resistor R52 is “intermediate”, and becomes “high” when the resistance value of the resistor R52 is “low”.

As shown in FIG. 16, in this case, the resistance value of the resistor R51 is switched at the rise timing of the control signal Sb, and thus the on-side drive capability is switched. Meanwhile, the resistance value of the resistor R52 is switched at the fall timing of the control signal Sb, and thus the off-side drive capability is switched. That is, also in this case, the on-side drive capability and the off-side drive capability are switched in a similar manner to the first embodiment. As a result, the slew rate of the trapezoidal wave output is changed in the same mode as in the first embodiment. Therefore, according to the present embodiment, the same effects as in the first embodiment are obtained.

### Sixth Embodiment

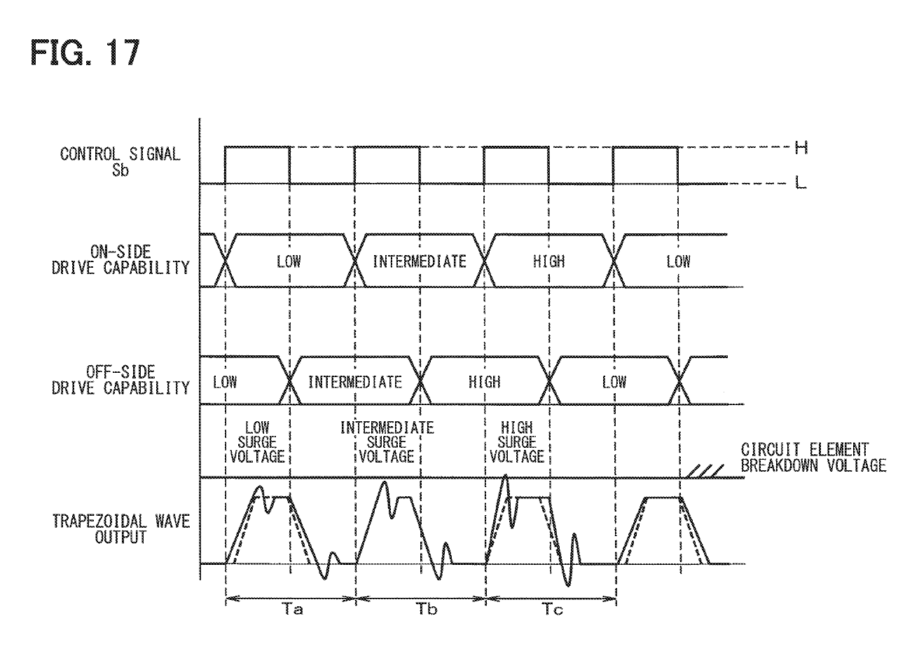

Hereinafter, a sixth embodiment will be described with reference to FIG. 17 to FIG. 19. As shown in FIG. 17, when the transistor T1 is turned on and off in the switching regulator 1 described in the first embodiment and the like, a surge voltage is generated in the trapezoidal wave output due to an influence of a parasitic inductance component or the like on the circuit. In addition, the above surge voltage is increased as the drive capability of the driver 4 is increased.

In a case where the surge voltage that is generated at the rise timing of the trapezoidal wave output is increased, a voltage value of the trapezoidal wave output is increased in a manner to exceed a breakdown voltage of a circuit element (the transistor T1, the diode D1, and the like), to which the trapezoidal wave output is applied. As a result, the circuit element possibly fails. In view of the above, in the present embodiment, a configuration for which a measure against such a problem is taken will be described.

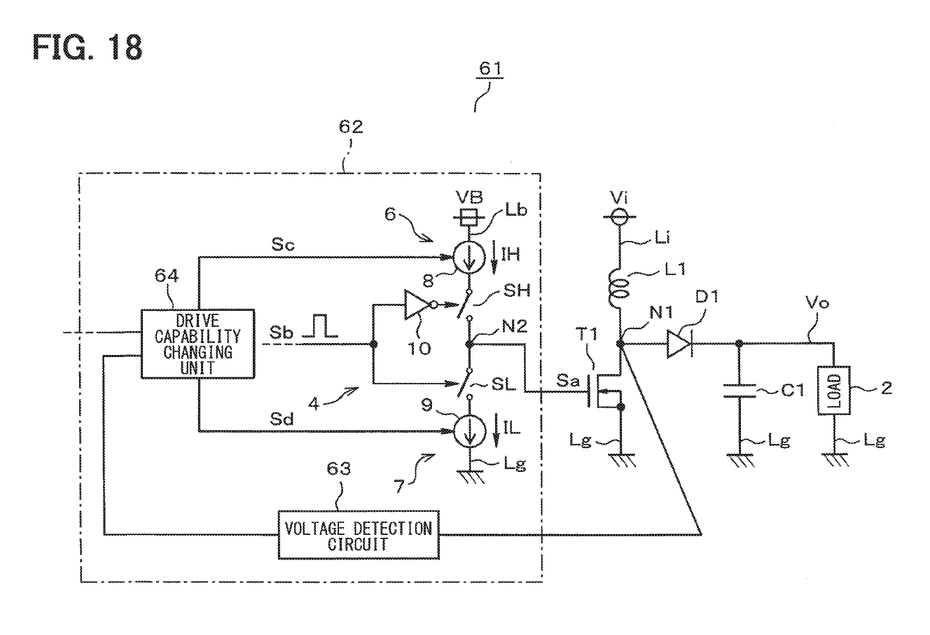

As shown in FIG. 18, a switching regulator 61 in the present embodiment differs from the switching regulator 1 shown in FIG. 1 in a point of including a drive circuit 62 instead of the drive circuit 3. Compared to the drive circuit 3, the drive circuit 62 further includes a voltage detection circuit 63 and includes a drive capability changing unit 64 instead of the drive capability changing unit 5. The voltage detection circuit 63 detects a voltage value of the node N1, that is, the voltage value of the trapezoidal wave output. A detection result of the voltage value by the voltage detection circuit 63 is provided to the drive capability changing unit 64.

Similar to the drive capability changing unit 5, the drive capability changing unit 64 periodically changes the drive capability of the driver 4. Furthermore, at predetermined time point in a rise period of the trapezoidal wave output (hereinafter called intervening switching time point), the drive capability changing unit 64 changes the drive capability of the driver 4 to be lower than the drive capability at the time point. More specifically, at the intervening switching time point in the rise period of the trapezoidal wave output when the off-side drive capability is “high”, the drive capability changing unit 64 changes the off-side drive capability to “intermediate”.

As the intervening switching time point described above, a time point at which the voltage value of the trapezoidal wave output reaches a predetermined switching threshold in the rise period of the trapezoidal wave output is set. The switching threshold only has to be an arbitrary value that is higher than a minimum value of the trapezoidal wave output and lower than a maximum value of the trapezoidal wave output. In the present embodiment, the switching threshold is set to a value that is approximately 80% of the maximum value, for example. The reason for setting the switching threshold to the value that is approximately 80% of the maximum value is as follows.

The surge voltage handled as the problem in the present embodiment is ringing that is generated after the trapezoidal wave output reaches the maximum value. Thus, the drive capability only has to be changed to the low value before the trapezoidal wave output reaches the maximum value. However, in a case where the switching threshold is set to a value that is approximately equal to the maximum value, the drive capability may not be changed in a timely manner due to responsiveness of the operation of each of the circuits and the like. Thus, in consideration of such a point, in the present embodiment, the switching threshold is set to a value that is slightly lower than the maximum value (for example, the value that is approximately 80% of the maximum value).

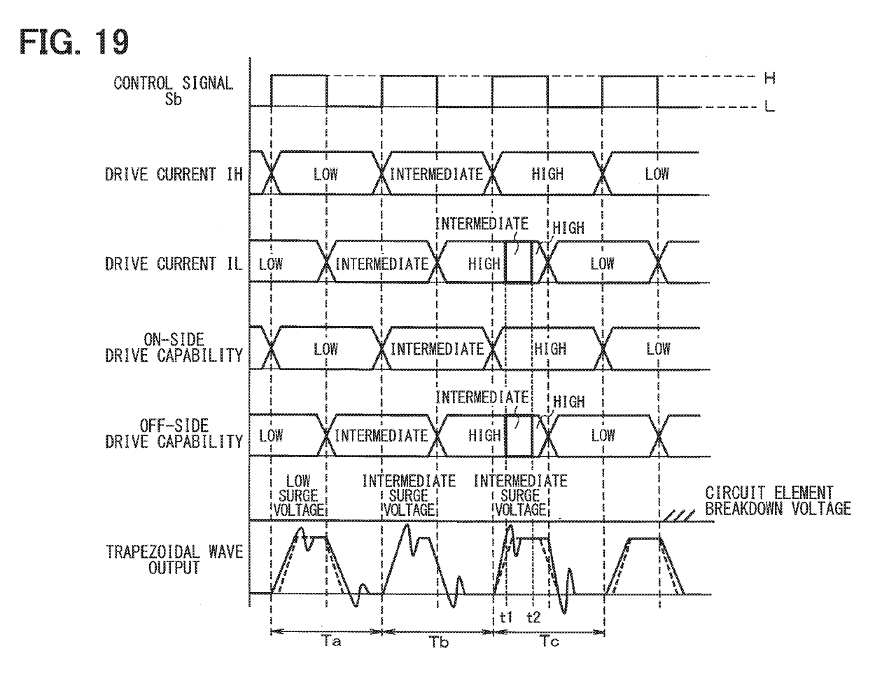

Next, operation and effects of the present embodiment will be described with reference to FIG. 19. In this case, periodical change intervals, the types, and the like of the drive capability are similar to periodical change intervals, the types, and the like in the first embodiment. Therefore, according to the present embodiment, the same effects as in the first embodiment are obtained. However, in this case, as shown in FIG. 19, the operation in the period Tc when the on-side drive capability and the off-side drive capability become “high” in conjunction with the periodical change of the drive capability differs.

That is, in the period Tc, at a time point t1 at which the voltage value of the trapezoidal wave output reaches the switching threshold (the intervening switching time point), the drive current IL is switched from “high” to “intermediate”, and thus the off-side drive capability is switched from “high” to “intermediate”. In this way, the surge voltage that is generated at the rise timing of the trapezoidal wave output in the period Tc is limited to the substantially same level (intermediate) as the surge voltage in the period Tb. Then, at a predetermined time point t2 before reaching the fall timing of the control signal Sb, the drive current IL is switched from “intermediate” to “high”, and thus the off-side drive capability returns from “intermediate” to “high”.

Accordingly, according to the present embodiment, similar to the first embodiment, the harmonic component contained in the rise and the fall of the trapezoidal wave output is dispersed, and thus the peak value of the noise can be suppressed to the low value. Furthermore, the failure of the circuit element, which is caused by the surge voltage generated at the rise timing of the trapezoidal wave output, can be prevented.

Note that, as a specific configuration of the drive circuit 62 excluding the voltage detection circuit 63, a configuration as shown in FIG. 2 can be adopted, for example. In this case, the voltage generation units 14, 16 are configured to be able to switch the voltage values of the reference voltages VREFP, VREFN, and the current mirror circuits 11, 12 are configured to be able to change the mirror ratios. As a voltage generation unit capable of switching the voltage value of each of the reference voltages VREFP, VREFN, any one of the configurations as shown in FIG. 3 to FIG. 6 can be adopted. In addition, as the current mirror circuit capable of changing the mirror ratio, the configuration as shown in FIG. 12 can be adopted.

In this case, the drive capability changing unit 64 periodically changes the drive capability by switching the reference voltages VREFP, VREFN and changes the drive capability at the intervening switching time point in the rise period of the trapezoidal wave output by switching the mirror ratios. More specifically, the drive capability changing unit 64 periodically changes the drive capability to the three stages of “low”, “intermediate”, and “high” by switching the reference voltages VREFP, VREFN to the three the voltage values V1 to V3 in the similar manner to the first embodiment. In addition, the drive capability changing unit 64 usually sets the mirror ratio to “high”, and sets the mirror ratio to “intermediate” until a predetermined period elapses from the intervening switching time point. In this way, the change (the decrease) of the drive capability in the rise period of the trapezoidal wave output is realized.

Since the change of the drive capability in the rise period of the trapezoidal wave output has to be completed before the generation of the surge voltage, high-speed response is required. In addition, as described in the third embodiment, the change of the drive capability by switching of the mirror ratio of the current mirror circuits 11, 12 exhibits the superior responsiveness to the change of the drive capability by another change method. Accordingly, as described above, in a case where the drive capability in the rise period of the trapezoidal wave output is changed by switching the mirror ratio, the responsiveness of the change is improved. Thus, the change of the drive capability can reliably be completed before the generation of the surge voltage.

### Seventh Embodiment

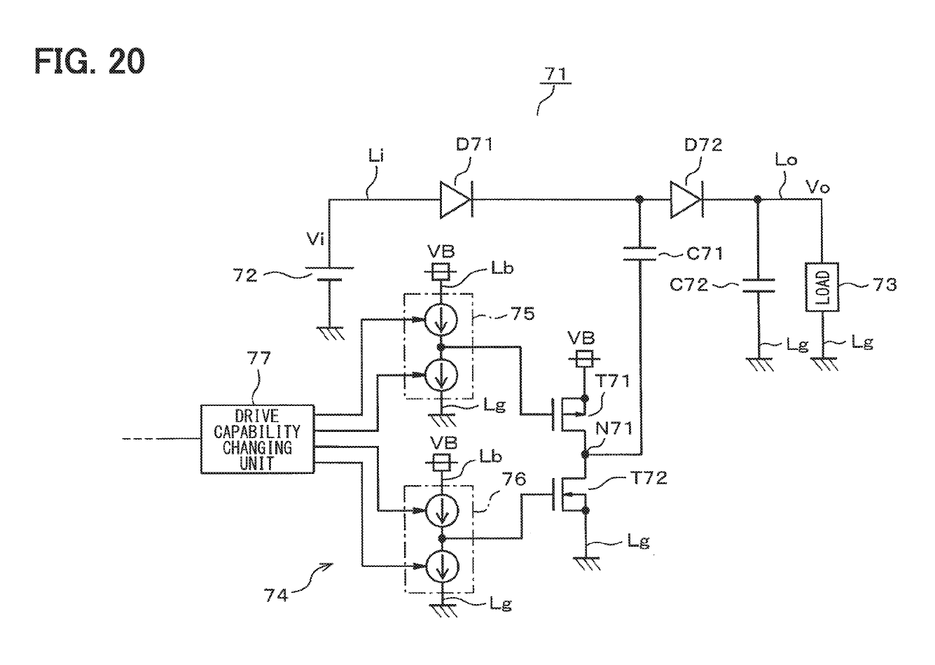

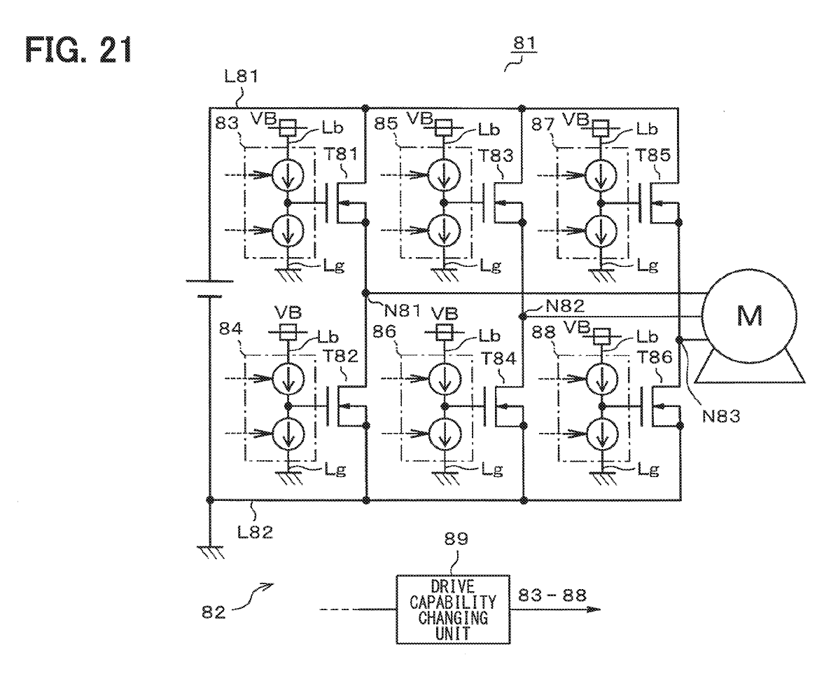

A seventh embodiment will hereinafter be described with reference to FIG. 20 and FIG. 21. In each of the above embodiment, the description has been made on the example in which the signal output circuit according to the present disclosure is applied to the switching regulator 1. However, the signal output circuit according to the present disclosure can be applied to all types of configurations, in each of which the trapezoidal wave output signal is output from the main terminal of the output transistor by controlling driving of the output transistor. For example, the signal output circuit according to the present disclosure can be applied to a charge pump circuit 71 shown in FIG. 20, a motor drive system 81 shown in FIG. 21, and the like.

As shown in FIG. 20, the charge pump circuit 71 has a general configuration that includes diodes D71, D72 and capacitors C71, C72. The charge pump circuit 71 boosts and outputs the input voltage Vi that is received from a DC power supply 72 through the input power supply line Li. The output voltage Vo of the charge pump circuit 71 is supplied to a load 73 through the output power supply line Lo.

Between the input power supply line Li and the output power supply line Lo, the diodes D71, D72 are connected in series with the input power supply line Li side being an anode. The smoothing capacitor C72 is connected between the output power supply line La and a ground line Lg. One terminal of the capacitor C71 is connected to a mutual connection node N71 of the diodes D71, D72.

The other terminal of the capacitor C71 receives the trapezoidal wave output that is output from the mutual connection node N71 of two transistors T71, T72 that are connected in series between the power supply line Lb and the ground line Lg. The transistor T71 is the p-channel MOS transistor, and the transistor T72 is the n-channel MOS transistor. In this case, each of the transistors T71, T72 corresponds to the output transistor, and a drain of each of the transistors T71, T72 corresponds to the main terminal.

The transistors T71, T72 are driven by a drive circuit 74 that corresponds to the signal output circuit. The drive circuit 74 includes drivers 75, 76 that respectively drive the transistors T71, T72 at the constant current and a drive capability changing unit 77 that periodically changes drive capability of each of the drivers 75, 76.

In the above configuration, since the drive capability of each of the drivers 75, 76 is periodically changed by the drive capability changing unit 77, the slew rate of the trapezoidal wave output that is applies to the other terminal of the capacitor C71 is periodically changed. Accordingly, also with the above configuration, similar to the first embodiment, the harmonic component contained in the rise and the fall of the trapezoidal wave output is dispersed, and thus the peak value of the noise can be suppressed to the low value.

The motor drive system 81 shown in FIG. 21 is used for a main machine inverter or an integrated starter generator (ISG), for example and is a system that drives a three-phase motor M. The motor drive system 81 includes six transistors T81 to T86 that are connected between paired DC power supply lines L81, L82 in a form a three-phase full bridge and a drive circuit 82 that drives those transistors T81 to T86.

In this case, the trapezoidal wave output that is output from each of a mutual connection node N81 of the transistors T81, T82, a mutual connection node N82 of the transistors T83, T84, and a mutual connection node N83 of the transistors T85, T86 is applied to the motor M. Thus, each of the transistors T81 to T86 corresponds to the output transistor, and a source of each of the transistors T81, T83, T85 and a drain of each of the transistors T82, T84, T86 correspond to the main terminals.

The drive circuit 82 includes drivers 83 to 88 that respectively drive the transistors T81 to T86 at the constant current and a drive capability changing unit 89 that periodically changes the drive capability of each of the drivers 83 to 88. In the above configuration, since the drive capability of each of the drivers 83 to 88 is periodically changed by the drive capability changing unit 89, the slew rate of the trapezoidal wave output that is output from each of the mutual connection nodes N81, N82 to the motor M2 is periodically changed. Accordingly, also with the above configuration, similar to the first embodiment, the harmonic component contained in the rise and the fall of the trapezoidal wave output is dispersed, and thus the peak value of the noise can be suppressed to the low value.

### Other Embodiments

The present disclosure is not limited to the embodiments that have been described above and illustrated in the drawings, but can arbitrarily be modified, combined, or expanded without departing from the gist of the present disclosure.

In each of the above embodiments, the drive capability is changed such that the on-side drive capability and the off-side drive capability become the same in each PWM cycle. However, the drive capability may be changed such that the on-side drive capability and the off-side drive capability differ from each other in each cycle.

The drive capability does not have to be changed every cycle but may be changed every multiple cycles, for example. However, in such a case, the drive capability is preferably changed every multiple cycles such that the variation in the loss does not appear clearly.

The change patterns the drive capability is not limited to the three types but may be two types, four types, or more. In the sixth embodiment, in the rise period of the trapezoidal wave output, the drive capability is changed by switching the mirror ratio. However, the change method of the drive capability is not limited to the change method by switching the mirror ratio. The drive capability may be changed by using any of the various change methods that have been described in the above embodiments.

The present disclosure is described based on the embodiments, and it is understood that present disclosure is not limited to the embodiments or the structures. The present disclosure encompasses various modifications and variations within the scope of equivalents. Furthermore, various combinations and forms, and furthermore, other combinations and forms including only one element, more elements, or less elements are included within the range and the scope of the present disclosure.

What is claimed is:

1. A signal output circuit configured to control driving of an output transistor to output a trapezoidal wave output signal from a main terminal of the output transistor, the signal output circuit comprising:
a driver that drives the output transistor at a constant current; and
a drive capability changing unit that periodically changes drive capability of the driver, wherein
the drive capability changing unit changes the drive capability such that a difference between a slew rate of the trapezoidal wave output signal before a change of the drive capability and the slew rate of the trapezoidal wave output signal after the change of the drive capability becomes smaller than a predetermined threshold, and
the predetermined threshold is set such that the least common multiple of a frequency determined at the slew rate of the trapezoidal wave output signal before the change of the drive capability and a frequency determined at the slew rate of the trapezoidal wave output signal after the change of the drive capability becomes equal to or higher than a predetermined frequency.

2. The signal output circuit according to claim 1, wherein
a switching time point at which the drive capability of the driver is changed is set in a period when the trapezoidal wave output signal is not changed.

3. The signal output circuit according to claim 1, wherein
the drive capability changing unit changes the drive capability of the driver at a predetermined intervening switching time point in a rise period or a fall period of the trapezoidal wave output signal to be lower than the drive capability before changing.

4. The signal output circuit according to claim 1, wherein
the driver includes a current generation circuit that generates a drive current for driving the output transistor, and
the drive capability changing unit changes the drive capability by changing a magnitude of the drive current generated by the current generation circuit.

5. The signal output circuit according to claim 4, wherein
the current generation circuit includes a current mirror circuit in an output stage, and
the drive capability changing unit changes the magnitude of the drive current by changing a current on an input side of the current mirror circuit.

6. The signal output circuit according to claim 4, wherein
the current generation circuit includes a current mirror circuit n an output stage, and
the drive capability changing unit changes the magnitude of the drive current by changing a mirror ratio of the current mirror circuit.

7. The signal output circuit according to claim 1, wherein
the drive capability changing unit changes the drive capability of the driver every cycle of the trapezoidal wave output signal.

8. The signal output circuit according to claim 1, wherein
the drive capability changing unit changes the drive capability of the driver to three or more types of the drive capability.

9. A signal output circuit configured to control driving of an output transistor to output a trapezoidal wave output signal from a main terminal of the output transistor, the signal output circuit comprising:
a driver that drives the output transistor at a constant current; and
a drive capability changing unit that periodically changes drive capability of the driver, wherein
the driver includes an on-side driver that drives the output transistor on and an off-side driver that drives the output transistor off, and
the drive capability changing unit changes drive capability of the off-side driver by using initiation of on-driving by the on-side driver as a trigger, and changes drive capability of the on-side driver by using initiation of off-driving by the off-side driver as a trigger.
